(19) United States
(12) Patent Application Publication
(10) Pub. No.: US 2025/0266344 A1
(43) Pub. Date: Aug. 21, 2025

(54) BACK END OF THE LINE WIRING BETWEEN DEVICE LAYERS

(71) Applicant: INTERNATIONAL BUSINESS MACHINES CORPORATION, Armonk, NY (US)

(72) Inventors: Brent A. Anderson, Jericho, VT (US); Nicholas Anthony Lanzillo, Wynantskill, NY (US); Albert M. Chu, Nashua, NH (US); David Wolpert, Poughkeepsie, NY (US); Ruilong Xie, Niskayuna, NY (US); Lawrence A. Clevenger, Saratoga Springs, NY (US)

(21) Appl. No.: 18/583,082

(22) Filed: Feb. 21, 2024

(51) Int. Cl. H01L 23/498; H01L 21/027; H01L 21/762; H01L 25/065

(52) U.S. Cl. CPC H01L 23/49838; H01L 21/0274; H01L 21/76224; H01L 25/0652

(57) ABSTRACT

In an embodiment, a semiconductor structure is provided that includes a stacked structure of a first device level and a second device level. A middle back end of the line (BEOL) level is positioned between the first device level and the second device level. The middle back end of the line (BEOL) level includes a first wiring layer in electrical communication with the first device level and a second wiring layer in electrical communication with the second device level, wherein a second pitch for metal lines in the second wiring layer is greater than a first pitch for metal lines in the first wiring layer. The semiconductor device structure further includes a frontside back end of the line (BEOL) level above the second device level.

### BACKGROUND

The present invention generally relates to electrical devices, and more particularly to layouts for metal lines for distributing signal and powering microelectronic devices.

Modern semiconductor packages are formed from multiple stacked material layers that may include numerous active devices electrically coupled together by conductive metal interconnects and lines. Interconnect structures including metallization lines connect various components of semiconductor integrated circuits (ICs). The metallization lines within each interconnect layer are formed in an interlayer dielectric (ILD) material, such as a low-k dielectric. The ILD material electrically isolates metallization lines from one another within each level and in adjacent levels of interconnect structures.

Back end-of-line (“BEOL”) fabrication processes are used to create an intricate network of conductive interconnects in each layer and between the multiple layers. Damascene processes including a single damascene process and a dual-damascene process are routinely used for fabricating multi-level interconnect structures. In a damascene process, trenches and via holes are made inside and through an ILD layer, and filled with a conductive material, such as copper (Cu) or a Cu-based alloy, to create metallization lines and vertical conductive paths (vias) between adjacent layers.

### SUMMARY

In an embodiment, a semiconductor device is provided that includes a stacked structure of a first device level and a second device level. A middle back end of the line (BEOL) level is positioned between the first device level and the second device level. The middle back end of the line (BEOL) level includes a first wiring layer in electrical communication with the first device level and a second wiring layer in electrical communication with the second device level. In some embodiments, a second pitch for metal lines in the second wiring layer is greater than a first pitch for metal lines in the first wiring layer. The second wiring layer including a lateral signal distribution bus extending from a first side of the semiconductor device to a second semiconductor device carrying signal to the first device level and the second device level. The semiconductor device structure further includes a frontside back end of the line (BEOL) level above the second device level.

In another embodiment, a semiconductor device is provided that includes a stacked structure of a first device level and a second device level. A middle back end of the line (BEOL) level is positioned between the first device level and the second device level. The middle back end of the line (BEOL) level includes a first wiring layer in electrical communication with the first device level and a second wiring layer in electrical communication with the second device level, wherein a second pitch for metal lines in the second wiring layer is greater than a first pitch for metal lines in the first wiring layer. The metal lines in the second wiring layer have a lesser resistance than the metal lines in the first wiring layer. The second wiring layer including a lateral signal distribution bus across a width of the device. The semiconductor device structure further includes a frontside back end of the line (BEOL) level in electrical communication with the second device level. A backside power network is in electrical communication with the first device level.

In another embodiment, a method of forming a semiconductor device is described that includes forming a first wiring layer on a first device level, and forming a second wiring layer on the first wiring layer to provide a middle back end of the line (BEOL) level. In some examples, a second pitch for second metal lines in the second wiring layer is greater than a first pitch for first metal lines in the first wiring layer. The method may also include forming a second device level on the middle back end of the line (BEOL) level.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a side cross-sectional view illustrating a semiconductor device including a middle back end of the line (BEOL) level between a first device level and a second device level, in accordance with an embodiment of the present invention;

FIG. 2 is a side cross-sectional view illustrating signal distribution in a middle back end of the line (BEOL) level, in accordance with an embodiment of the present invention;

FIG. 3 is a side cross-sectional view illustrating a clock circuit connection across a plurality of middle back end of the line (BEOL) levels, in accordance with an embodiment of the present invention;

FIG. 4 is a side cross-sectional view illustrating a clock circuit connection across a plurality of middle back end of the line (BEOL) levels, in accordance with an embodiment of the present invention;

FIG. 5 is a side cross-sectional view illustrating power distribution from the backside of a first device across the back end of the line (BEOL) levels, in accordance with an embodiment of the present invention;

FIG. 6 is a side cross-sectional view of forming a middle back end of the line (BEOL) layer on a first device level, in accordance with an embodiment of the present invention;

FIG. 7 is a side cross-sectional view of bonding a first carrier wafer to the structure depicted in FIG. 6, in accordance with an embodiment of the present invention;

FIG. 8 is a side cross-sectional view of forming a second device level on the middle back end of the line (BEOL) level, and forming a front back end of the line (BEOL) level on the second device level, in accordance with an embodiment of the present invention;

FIG. 9 is a side cross-sectional view of bonding a second carrier wafer to the structure depicted in FIG. 8, in accordance with an embodiment of the present invention; and

FIG. 10 is a side cross-sectional view of debonding the first carrier wafer from the structure depicted in FIG. 9, in accordance with an embodiment of the present invention.

### DETAILED DESCRIPTION

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

The structures and methods described herein provide a stacked semiconductor device that positions wiring for signal distribution in middle wiring levels of the stack, e.g., in a middle back end of the line (BEOL) level. By positioning the signal distribution wiring in the middle wiring levels of the stacked semiconductor device, large pitch and large cross-sectional wiring may be present in the device stack without introducing congestion to the top side of the device. The signal distribution wiring that is present in the middle wiring levels of the semiconductor device stack may provide bus signal and clock signal circuits to the different types of devices in the first device level and the second device level of the semiconductor device.

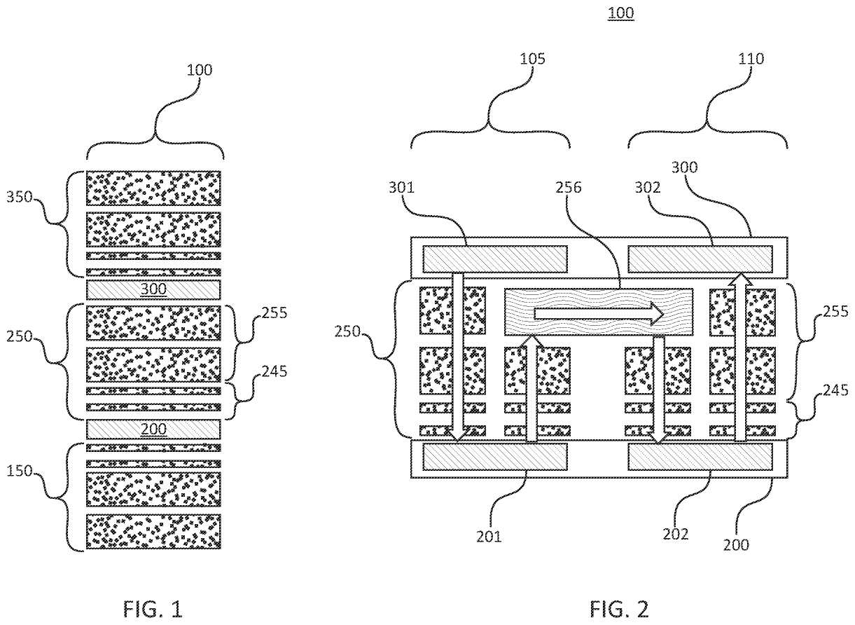

FIG. 1 is a side cross-sectional view illustrating a semiconductor device 100 including a middle back end of the line (BEOL) level 250 between a first device level 200 and a second device level 300. The first device level 200 and the second device level 300 are positioned in a stacked structure. The first device level 200 and the second device level 300 include semiconductor devices that are formed using front end of the line (FEOL) processing, as well as the interconnects to the semiconductor devices that are formed by middle of the line (MOL) processing. The semiconductor devices may include field effect transistors (FETs), fin field effect transistors (FinFETs), nanosheet channel semiconductor devices, vertical field effect transistors (VFETs) and combinations thereof. The semiconductor devices can also include memory chips, such as static random-access memory (static RAM or SRAM), dynamic random-access memory (DRAM), ferroelectric random access memory (FRAM), resistive processing unit (RPU) memory and combinations thereof. The semiconductor devices may be formed atop a semiconductor substrate, e.g., a type IV semiconductor substrate or a type III-V semiconductor substrate. In one example, the semiconductor substrate can be silicon based.

The front end of the line (FEOL) includes all the process steps that are related to the semiconductor devices themselves including the gate of a transistor. The back end of the line (BEOL) includes all subsequent process steps. In the back end of the line (BEOL), the various devices formed during the FEOL processing, e.g., active and passive devices, are being interconnected through metal lines.

The middle of the line (MOL) features to the semiconductor devices may be contacts, which can be a silicide to the electrical features of the semiconductor devices that are active, such as the source/drain regions and gate structures.

An intralevel dielectric may also be present providing isolation between the different middle of the line (MOL) contacts to the semiconductor devices. The combination of the semiconductor devices, the middle of the line (MOL) contacts and the substrate may provide a device level, such as the first device level 200 and the second device level 300.

Between the first device level 200 and the second device level 300 is the middle back end of the line (BEOL) level 250. The middle back end of the line (BEOL) level 250 includes a first wiring layer 245 in contact with the first device level 200 and a second wiring layer 255 in contact with the second device level 300. In some embodiments, a second pitch for second metal lines in the second wiring layer 255 is greater than a first pitch for first metal lines in the first wiring layer 245. The term “pitch” refers to a minimum center to center distance between metal lines. When referring to the minimum center to center distance, it is referring to a minimum dimension that is supported by the manufacturing process that can reproduced the structure. In some embodiments, the second pitch for the metal lines in the second wiring layer 255 is at least three (3×) times greater than the first pitch for the metal lines in the first wiring layer 245.

The first pitch separating adjacent metal lines in the first wiring layer 245 can be tight to accommodate the short length connections to the semiconductor devices in the first device level 200. In some embodiments, a number of first wire pathways in the first wiring layer 245 is greater than a number of second wire pathways in the second wiring layer 255. In some embodiments, the tighter pitch and higher density for the metal lines in the first wiring layer 245 provides that the first metal lines in the first wiring layer 245 has a lesser cross sectional area than the metal lines in the second wiring layer 255. This can result in the metal lines in the first wiring layer 245 having a higher resistance than the metal lines in the second wiring layer 255. However, the metal lines in the first wiring layer 245 having higher density and smaller cross-sectional area that is suitable for making contact to the plurality of contacts of the highly scaled semiconductor devices in the first device level 200.

The second pitch of the metal lines in the second wiring layer 255 is larger than the first pitch of the metal lines in the first wiring layer 245. In addition to the pitch for the metal lines in the second wiring layer 255 being bigger than the pitch of the metal lines in the first wiring layer 245, the cross-sectional area (Width×Height) for the metal lines in the second wiring layer 255 is greater than the cross-sectional area for the metal lines in the first wiring layer 245. By increasing the pitch and the cross-sectional area for the metal lines in the second wiring layer 255, the metal lines in the second wiring layer 255 have a lesser resistance than the metal lines in the first wiring layers 245. The lower resistance metal lines in the second wiring layer 255 are optimized for longer electrical signal communication pathways. The lower resistance metal lines in the second wiring layer 255 are more suitable for signal distribution, such as bus signal distribution and clock signal distribution, than the metal lines that are in the first wiring layer 245. For example, the second wiring layer 255 may include a lateral signal distribution bus 256. The lateral signal distribution bus 256 can transmit signal across the width of the second wiring layer 255 from the first side 105 of the device to the second side 110 of the device.

Referring to FIG. 1, the semiconductor device 100 also includes a frontside back end of the line (BEOL) level 350 that is atop the second device level 300. The frontside back end of the line (BEOL) level 350 includes metal lines that can provide signal distribution and/or power to the semiconductor devices in the second device level 300. In some embodiments, the density and number metal lines in the frontside back end of the line (BEOL) level 350 is less than prior designs. The density and/or metal lines in the frontside back end of the line (BEOL) level 350 of the embodiments described herein have a lesser density than prior designs, because at least some of the metal lines for power and signal distribution are present in the middle back end of the line (BEOL) level 250.

FIG. 1 also illustrates a backside power delivery network 150. The backside power delivery network 150 also reduces metal line density in the upper levels of the semiconductor device 100 when compared to devices having power delivered from the frontside of the semiconductor device 100. Backside power delivery refers to the technique of routing power supply lines on the backside of a semiconductor chip or integrated circuit (IC) instead of the traditional frontside. This approach increases logic density and improves power and performance.

FIG. 2 illustrates one embodiment of signal distribution in the middle back end of the line (BEOL) level 250. The signal depicted in FIG. 2 is one example of electrical communication across the first device level 200 and the second device level 300. In some embodiments, the middle back end of the line (BEOL) level 250 includes a bus circuit between the first device level 200 and the second device level 300. In some embodiments, the first device level 200 includes a first driver circuit 201 and a second driver circuit 202. The first driver circuit 201 is present on a first side 105 of the device and the second driver circuit 202 is present on a second side 110 of the device. In some embodiments, the second device level 300 includes a first logic bus 301 to send logic signals from the first side 105 of the device, and a second logic bus 302 to receive logic signals on the second side 106 of the device.

In some embodiments, the bus circuit may include a lateral signal distribution bus 256 in the second wiring layer 255 that is connecting the portions of the bus circuit from the first side 105 of the device to the second side 110 of the semiconductor device 100. The lateral signal distribution bus 256 includes metal wiring having the greater pitch and the greater cross sectional area of the second wiring layer 255 than the metal wiring in the first wiring layer 245. This provides low resistance metal wiring for transmitting long range signal, e.g., across the width of the device, such as from the first side 105 of the semiconductor device to the second side 110 of the semiconductor device.

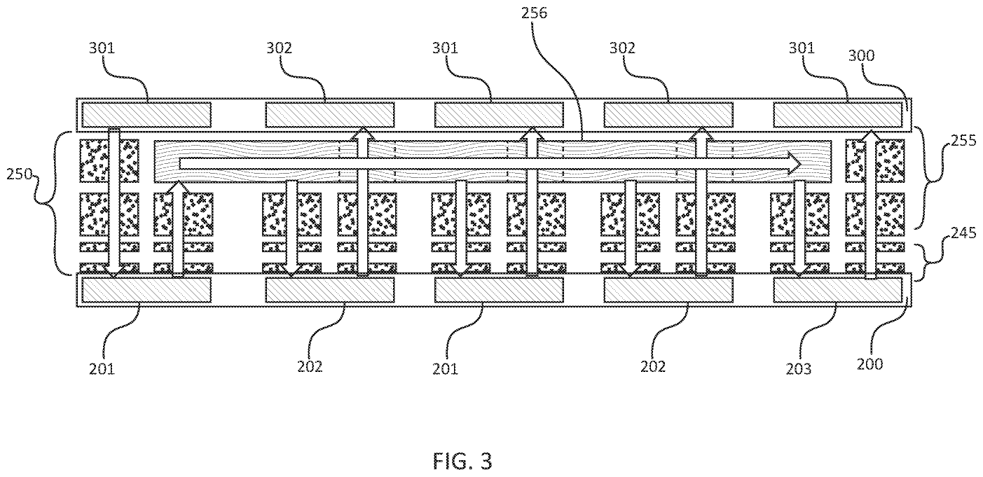

In an embodiment illustrated in FIG. 2, a logic signal can be first sent from the first logic bus 301 in the second device level 300 to first driver circuit 201 in the second device level 300 on the first side 105 of the device. From the first driver circuit 201, the logic signal is then sent to the lateral signal distribution bus 256 of the bus circuit, which carries the signal form the first side 105 of the device to the second side 110 of the device. Thereafter, from the lateral signal distribution bus 256 of the bus circuit, the signal is transmitted to the second driver circuit 202 in the first device level 200 on the second side 110 of the device. The logic signal can then be sent from the second driver circuit 202 to the second logic bus 302 in the second device level 300. The vertical connections pass through the first wiring layer 245 of the middle back end of the line (BEOL) level 250, which provides a tighter pitch and density for contacting the devices in the first device level 200. The wiring depicted in FIG. 2 can be employed for both clock and logic signal distribution. Further, the exact passageway of signal is not limited to only the example depicted in FIG. 2. Further, the signal being transmitted across the middle back end of the line (BEOL) level is not limited to one set of the first device level 200 and the second device level 300. For example, FIG. 3 illustrates one embodiment of a clock circuit connection across a plurality of middle back end of the line (BEOL) level 250. It is noted that the embodiment depicted in FIG. 3 is only one example of how a clock signal may be distributed.

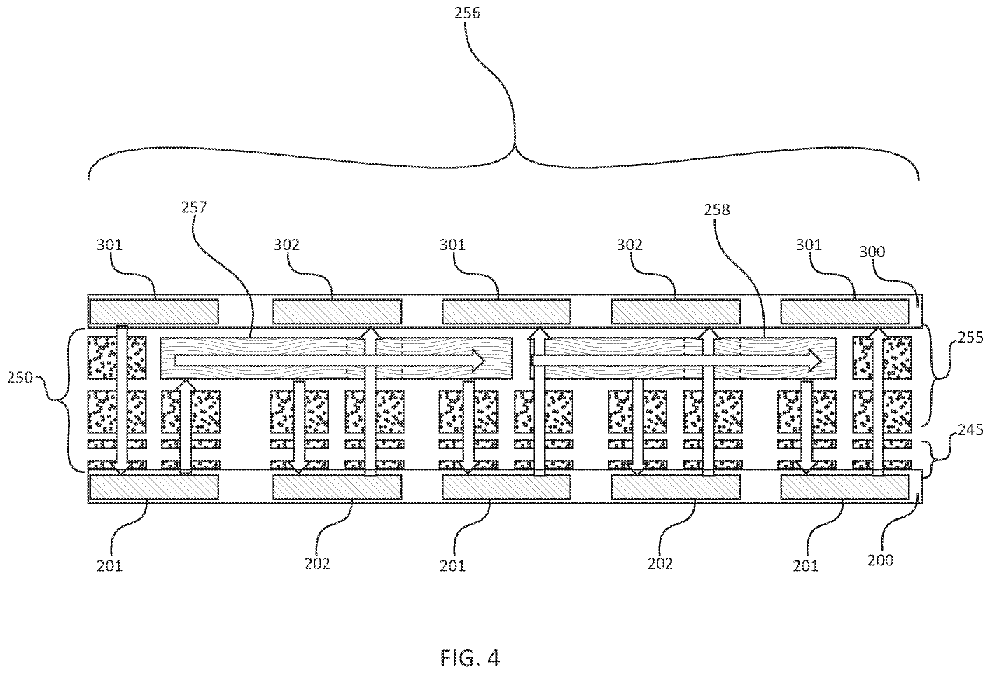

FIG. 4 illustrates a clock circuit connection across a plurality of middle back end of the line (BEOL) level 250 in which signal strength may be maintained by a repeater driver circuit 103. In the embodiments, in which the signal being distributed across the middle back end of the line (BEOL) layer is a clock signal, the repeater device circuit 203 increases the signal strength so that the number devices the clock signal reaches is increased.

In the embodiment depicted in FIG. 4, the lateral signal distribution bus 256 of the bus circuit is broken into two parts. For example, the first part 257 of the lateral signal distribution bus 256 for the bus circuit may transmit a clock signal to a first number of devices in the first device level 200 and the second device level 300, e.g., ten devices. At the end of the first part 257 of the lateral signal distribution bus 256 of the bus circuit, the clock signal may then be amplified by the repeater device circuit 203. Thereafter, the amplified clock signal is then transmitted across a second part 258 of the lateral signal distribution bus 256 for the bus circuit. The second part 258 of the lateral signal distribution bus 256 of the bus circuit may transmit the amplified clock signal to a second number of devices in the first device level 200 and the second device level 300, e.g., another ten devices.

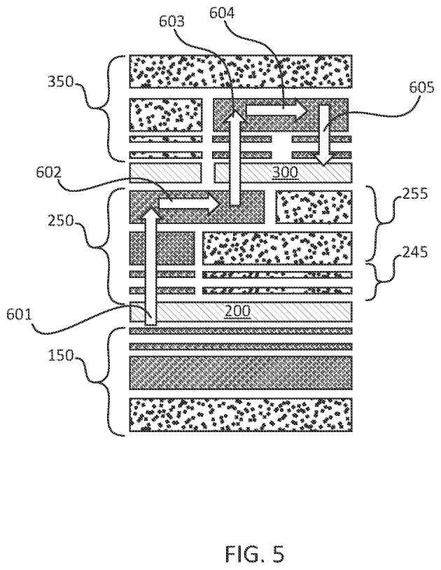

FIG. 5 illustrates power distribution throughout the semiconductor device 100 starting from the backside of the first device level 200. The backside power delivery network 150 reduces metal line density in the upper levels of the semiconductor device 100 when compared to devices having power delivered from the frontside of the semiconductor device 100. In the embodiment depicts in FIG. 5, power distribution begins in the backside power delivery network 150 and is transmitted to the devices in the first device level 200. A first portion 601 of the power distribution path extends from the backside power delivery network 150 through the first device level 200 and the first wiring layer 245 of the middle back end of the line (BEOL) level 250 to the lateral signal distribution bus 256 in the second wiring layer 255 of the middle back end of the line (BEOL) level 250. The second portion 602 of the power distribution path extends through the lateral signal distribution bus 256 in the second wiring layer 255 can benefit from the larger pitch and larger cross-sectional area for low resistance transmission of power that provides for a lesser resistance to power distribution than the tighter pitch and lesser cross-sectional area for the metal lines outside the second wiring layer 255. A third portion 603 of the power distribution path can then provide power to the second device level 300. In some embodiments, a fourth portion 604 of the power distribution transmits power across the width of the second device level 300 and can be present in the frontside back end of the line (BEOL) level 350. In some embodiments, a fifth portion 605 of the power distribution can provide for electrical communication of the devices in the second device level 300. It is noted that the power distribution pathways illustrated in FIG. 5 represent only one embodiment of the present disclosure.

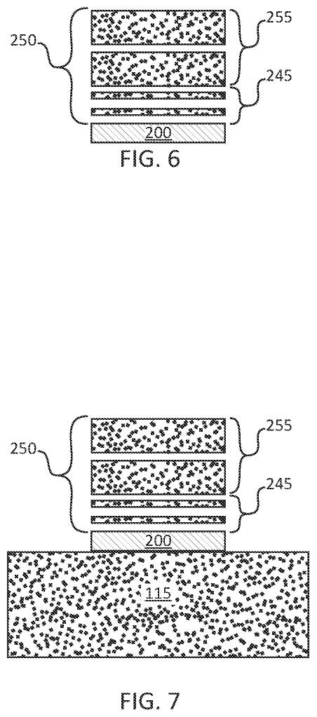

FIG. 6 illustrates one embodiment of an initial structure that can be used in a method for forming the semiconductor device 100 that is depicted in FIGS. 1-5. The initial structure can include the first device level 200 and the middle back end of the line (BEOL) level 250. The first device level 200 may be formed on a semiconductor substrate, such as a type IV semiconductor substrate or a type III-V semiconductor substrate. For example, the type IV semiconductor substrate may be a silicon type substrate.

The semiconductor devices within the first device level 200 may be formed using deposition, etch and dopant implantation methods. For example, the semiconductor devices may include field effect transistors (FETs), fin field effect transistors (FinFETs), nanosheet channel semiconductor devices, vertical field effect transistors (VFETs) and combinations thereof. The semiconductor devices can also include memory chips, such as static random-access memory (static RAM or SRAM), dynamic random-access memory (DRAM), ferroelectric random access memory (FRAM), resistive processing unit (RPU) memory and combinations thereof.

Further, photolithography may be employed to process individual portions of the layers at a time. The process steps used to form the semiconductor devices are front end of the line processes. Middle of the line (MOL) processes may be employed to provide contacts to source/drain and gate structures for the semiconductor devices of the first device level 200.

FIG. 6 further illustrates forming the middle back end of the line (BEOL) level 250 on the first device level 200. Forming the middle back end of the line (BEOL) level 250 can start with forming a first wiring layer 245. The first wiring layer 245 can have a narrower pitch than the second wiring layer 255. The first wiring layer 245 include at least some metal lines that are in contact with the semiconductor devices in the first device level 200. The first wiring layer 245 can be formed using deposition, photolithography, etching and planarization processes.

In some examples, forming the first wiring layer 245 can include depositing an interlevel dielectric layer followed by forming vias in the interlevel dielectric to form vias to form openings to the underlying contacts for the semiconductor devices in the first device level 200. The interlevel dielectric may be selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). Additional choices for the interlevel dielectric layer include any of the aforementioned materials in porous form, or in a form that changes during processing to or from being porous and/or permeable to being non-porous and/or non-permeable. The interlevel dielectric layer may be deposited using at least one of spinning from solution, spraying from solution, chemical vapor deposition (CVD), plasma enhanced CVD (PECVD), sputter deposition, reactive sputter deposition, ion-beam deposition, and evaporation

After depositing the interlevel dielectric layer, via openings may be formed and filled with an electrically conductive material, such as a metal, e.g., copper, to provide vias. The vias are in communication with the contacts of the semiconductor devices. Thereafter, a deposition, pattern and fill sequence is repeated to forms lines.

Patterning can be performed using photolithography. For example, a pattern is produced by applying a photoresist to the surface to be etched; exposing the photoresist to a pattern of radiation; and then developing the pattern into the photoresist utilizing conventional resist developer. Once the patterning of the photoresist is completed, the sections covered by the photoresist are protected while the exposed regions are removed using a selective etching process that removes the unprotected regions. The distance separating portions of the photoresist mask used in etching trenches in the interlevel dielectric layer ultimately define the pitch for the metal lines. Following patterning, an etch process may form the openings for vias and trenches for metal lines in the interlevel dielectric layer. The etch process may be an anisotropic etch process, such as reactive ion etching (RIE). In some embodiments, the metal for the vias and metal lines may be deposited using a plating process. The plating process may include electroplating or electroless plating. In some embodiments, the metal composition for the metal lines may be copper. The metal lines may also include a liner, such as tantalum or tantalum nitride liner, which can control copper diffusion.

Following deposition of the metal, for the lines and vias, a planarization process, such as chemical mechanical planarization (CMP) may be employed.

Forming the vias using a first sequence of pattern, etch and deposition may be referred to as a single damascene method for forming lines and vias. However, dual damascene sequences are also applicable for forming the metal wires in the middle back end of the line (BEOL) level 250. The sequence of deposition, pattern and etch are repeated as many times as needed to form each level of metal lines and vias. For example, the sequence of deposition, pattern and etch may be repeated multiple times to provide that the middle back end of the line (BEOL) level 250 includes the first wiring layer 245 having the first pitch, and the second wiring layer 255 having the second pitch. The second pitch of the second wiring layer 255 is greater than the first pitch of the first metal wiring layer to provide that the metal lines in the second wiring layer 255 have a lesser resistance than the metal lines in the first wiring layer 245.

FIG. 7 depicts bonding a first carrier wafer 115 to the structure depicted in FIG. 6. The first carrier wafer 115 may be composed of a semiconductor or insulating material, and provides structural support for the device. In some embodiments, the first carrier wafer 115 is bonded to the backside of the first device level 200. In some embodiments, the bonding step is provided by adhesive bonding.

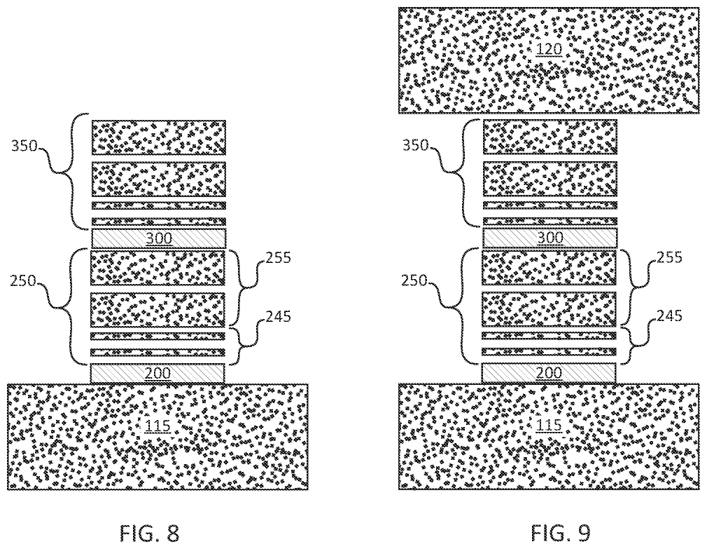

FIG. 8 depicts one embodiment of forming a second device level 300 on the middle back end of the line (BEOL) level 250.

The second device level 300 may be formed on a semiconductor substrate, such as a type VI semiconductor substrate or a type III-V semiconductor substrate. The semiconductor devices within the second device level 300 may be formed using deposition, etch and dopant implantation methods. Further, photolithography may be employed to process individual portions of the layers at a time. The process steps used to form the semiconductor devices are front end of the line processes. Middle of the line (MOL) processes may be employed to provide contacts to source/drain and gate structures for the semiconductor devices of the second device level 300.

FIG. 8 further depicts forming a frontside back end of the line (BEOL) level 350 on the second device level 300. In some examples, forming the frontside back end of the line (BEOL) level 350 can include depositing an interlevel dielectric layer followed by forming vias in the interlevel dielectric to form vias to form openings to the underlying contacts for the semiconductor devices in the second device level 300. The interlevel dielectric may be selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). Additional choices for the interlevel dielectric layer include any of the aforementioned materials in porous form, or in a form that changes during processing to or from being porous and/or permeable to being non-porous and/or non-permeable. The interlevel dielectric layer may be deposited using at least one of spinning from solution, spraying from solution, chemical vapor deposition (CVD), plasma enhanced CVD (PECVD), sputter deposition, reactive sputter deposition, ion-beam deposition, and evaporation.

After depositing the interlevel dielectric layer, via openings may be formed and filled with an electrically conductive material, such as a metal, e.g., copper, to provide vias. The vias are in communication with the contacts of the semiconductor devices. Thereafter, a deposition, pattern and fill sequence is repeated to forms lines.

Patterning can be performed using photolithography. For example, a pattern is produced by applying a photoresist to the surface to be etched; exposing the photoresist to a pattern of radiation; and then developing the pattern into the photoresist utilizing conventional resist developer. Once the patterning of the photoresist is completed, the sections covered by the photoresist are protected while the exposed regions are removed using a selective etching process that removes the unprotected regions. The distance separating portions of the photoresist mask used in etching trenches in the interlevel dielectric layer ultimately define the pitch for the metal lines. Following patterning, an etch process may form the openings for vias and trenches for metal lines in the interlevel dielectric layer. The etch process may be an anisotropic etch process, such as reactive ion etching (RIE). In some embodiments, the metal for the vias and metal lines may be deposited using a plating process. The plating process may include electroplating or electroless plating. In some embodiments, the metal composition for the metal lines may be copper. The metal lines may also include a liner, such as tantalum or tantalum nitride liner, which can control copper diffusion. Following deposition of the metal, for the lines and vias, a planarization process, such as chemical mechanical planarization (CMP) may be employed.

FIG. 9 depicts one embodiment of bonding a second carrier wafer 120 to the structure depicted in FIG. 8. The second carrier wafer 120 may be composed of a semiconductor or insulating material, and provides structural support for the device. In some embodiments, the second carrier wafer 120 is bonded to the front of the frontside back end of the line level (BEOL) 350. In some embodiments, the bonding step is provided by adhesive bonding.

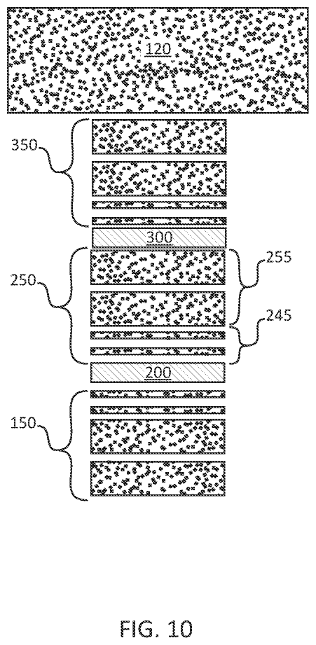

FIG. 10 depicts one embodiment of debonding the first carrier wafer 115 from the structure depicted in FIG. 9. Debonding may be achieved using thermal methods, such as laser ablation. In other embodiments, a solvent may be used to remove the adhesive.

FIG. 10 also depicts forming a backside power delivery network 150. The backside power delivery network 150 is designed to provide power supply and reference voltage (i.e., VDD and VSS) to the active devices on the structure, e.g., the semiconductor devices in the first device level 200 and the second device level 300. The backside power delivery network 150 shares this space with the signal network, i.e., the interconnects that are designed to transport the signal.

Following the formation of the backside power delivery network 150 the second carrier wafer 120 maybe removed. Debonding may be achieved using thermal methods, such as laser ablation. In other embodiments, a solvent may be used to remove the adhesive. It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a device including back end of the line wiring between device layers (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising:
a stacked structure of a first device level and a second device level;
a middle back end of a line (BEOL) level positioned between the first device level and the second device level, the middle back end of the line (BEOL) level includes a first wiring layer in electrical communication with the first device level and a second wiring layer in electrical communication with the second device level, wherein a second pitch for metal lines in the second wiring layer is greater than a first pitch for metal lines in the first wiring layer; and
a frontside back end of the line (BEOL) level above the second device level.

2. The semiconductor device of claim 1, wherein the second pitch is at least three times greater than the first pitch.

3. The semiconductor device of claim 1, wherein a number of first wire pathways in the first wiring layer is greater than a number of second wire pathways in the second wiring layer.

4. The semiconductor device of claim 1, wherein the middle back end of the line (BEOL) level includes a bus circuit between the first device level and the second device level.

5. The semiconductor device of claim 1, wherein a bus circuit includes a lateral signal distribution bus in the second wiring layer that is connecting a bus send logic portion of a circuit in a first side of the middle back end of the line (BEOL) to a bus receive portion of the circuit in a second side of the middle back end of the line (BEOL).

6. The semiconductor device of claim 5, wherein the bus send logic portion includes logic send wiring on the second device level connected to a first driver circuit on the first device level through a first vertical connecting portion, and a second vertical connecting portion for connecting the first driver circuit to the lateral signal distribution bus.

7. The semiconductor device of claim 5, wherein a bus receive logic portion includes a second driver circuit on the first device level that is connected to the lateral signal distribution bus by a third vertical connecting portion, the second driver circuit connected to logic receive wiring on the second device level by the third vertical connecting portion.

8. The semiconductor device of claim 5, wherein the lateral signal distribution bus in in electrical communication with a repeater driver circuit.

9. A semiconductor device comprising:
a stacked structure of a first device level and a second device level;
a middle back end of a line (BEOL) level positioned between the first device level and the second device level, the middle back end of the line (BEOL) level includes a first wiring layer in electrical communication with the first device level and a second wiring layer in electrical communication with the second device level, wherein a second pitch for metal lines in the second wiring layer is greater than a first pitch for metal lines in the first wiring layer;
a frontside back end of the line (BEOL) level in electrical communication with the second device level; and
a backside power network is in electrical communication with the first device level.

10. The semiconductor device of claim 9, wherein the second pitch is at least three times greater than the first pitch.

11. The semiconductor device of claim 9, wherein a number of first wire pathways in the first wiring layer is greater than a number of second wire pathways in the second wiring layer.

12. The semiconductor device of claim 9, wherein the middle back end of the line (BEOL) level includes a bus circuit between the first device level and the second device level.

13. The semiconductor device of claim 9, wherein vertically orientated electrical wiring is in the first wiring layer.

14. The semiconductor device of claim 13, wherein laterally orientated electrical wiring is in the second wiring layer.

15. A method of forming a semiconductor device comprising:
forming first wiring layers on a first device level;
forming second wiring layers on the first wiring layers to provide a middle back end of a line (BEOL) level, wherein a second pitch for metal lines in the second wiring layers is greater than a first pitch for metal lines in the first wiring layers; and
forming a second device level on the middle back end of the line (BEOL) level.

16. The method of claim 15, further comprising forming a backside power network on the first device level.

17. The method of claim 15, wherein the middle back end of the line (BEOL) level includes a bus circuit between the first device level and the second device level.

18. The method of claim 17, wherein the bus circuit includes a lateral signal distribution bus in the second wiring layers that is connecting a bus send logic portion of a circuit in a first side of the middle back end of the line (BEOL) to a bus receive portion of the circuit in a second side of the middle back end of the line (BEOL).

19. The method of claim 18, wherein the bus send logic portion includes logic send wiring on the second device level connected to a first driver circuit on the first device level through a first vertical connecting portion, and a second vertical connecting portion for connecting the first driver circuit to the lateral signal distribution bus.

20. The method of claim 19, wherein the lateral signal distribution bus in in electrical communication with a repeater driver circuit.
